(19) United States
(12) Patent Application Publication
(10) Pub. No.: US 2006/0110919 A1
(43) Pub. Date: May 25, 2006

(54) Method of forming a wiring pattern, method of manufacturing a device, device, electro-optic device, and electronic instrument

(75) Inventors: Katsuyuki Moriya, Azumino (JP); Toshimitsu Hirai, Chino (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/260,748

(22) Filed: Oct. 27, 2005

(30) Foreign Application Priority Data
Nov. 24, 2004 (JP) 2004-338517

(51) Int. Cl. H01L 21/44

(52) U.S. Cl. 438/675

(57) ABSTRACT

A method of forming a wiring pattern in a predetermined area on a substrate using a droplet ejection process, including the steps of (a) forming a recess section for disposing a functional fluid in the predetermined area so that the predetermined area has a first region, a second region connected to the first region, and the third region connected to the second region, the second region having a narrower width than the first region and the third region, (b) ejecting to the first region the functional fluid containing a material for the wiring pattern, (c) drying the functional fluid ejected to the first region to form a film, (d) ejecting the functional fluid to the third region, and (e) drying the functional fluid ejected to the third region to form a film.

### BACKGROUND OF THE INVENTION

1. Technical Field

The present invention relates to a method of forming a wiring pattern, a method of manufacturing a device, a device, an electro-optic device, and an electronic instrument.

2. Related Art

For manufacturing devices equipped with wiring used for electronic circuits or integrated circuits, a photolithography process, for example, is used. In the photolithography process, a thin film wiring pattern is formed by coating a surface of a substrate previously provided with a conductive film with a photosensitive material called resist, irradiating with a light beam to expose and develop the circuit pattern, and then etching the conductive film in accordance with the resist pattern. The photolithography process requires a large-scale facility such as a vacuum device and complicated processes, and has availability of materials as low as a few percent, which causes almost all materials be wasted, and accordingly, results in a high manufacturing cost.

For example, as disclosed in JP-A-11-274671 and JP-A-2000-216330, a method of forming a wiring pattern on a substrate using a droplet ejection process for ejecting functional fluid, which is a liquid material, from a droplet ejection head as droplets has been proposed. According to this method, a functional fluid for the wiring pattern, which is a functional fluid dispersing conductive fine particles such as metal particles, is disposed directly on a pattern forming area of the substrate, and then turning it into a conductive pattern by a thermal treatment or laser irradiation. According to this method, the photolithography process can be omitted, thus providing an advantage of dramatically simplifying the process while reducing consumption of the materials.

However, according to the wiring pattern forming method of the related art described above, the wiring pattern is formed by ejecting the functional fluid to the section, on which the gate wiring is to be formed, using the droplet ejection process. In the method, in this case, the functional fluid dropped on the gate wiring forming section flows toward a section to which a gate electrode is to be formed by a capillary phenomenon, thus the section for forming the gate wiring and the section for forming the gate electrode are filled with the functional fluid. However, since the section for forming the gate wiring is made wider than the section for forming the gate electrode, more of the function fluid dropped thereon is absorbed by the section for forming the gate wiring and is accumulated there. And, in some cases, the functional fluid does not sufficiently pervade the section for forming the gate electrode. And further, the wiring pattern obtained after calcining the functional fluid sometimes has uneven thickness in the section for forming the gate electrode, which is narrower than the section for forming the gate wiring. This sometimes causes an insufficient film thickness or a quality problem such as breaking of wiring pattern. If the thickness of the section for forming the gate electrode is too thin, the wiring resistance as the wiring pattern tends to increase, resulting in the phenomenon of decreasing in the driving performance of pixels. Therefore, as a result, it is difficult to provide a stable transistor performance.

### SUMMARY

An advantage of the invention is to provide a method of forming a wiring pattern, a method of manufacturing a device, a device, an electro-optic device, and an electronic instrument capable of reducing quality problems such as breaking lines in forming the wiring pattern.

A method of forming a wiring pattern according to an aspect of the invention is a method of forming a wiring pattern in a predetermined area on a substrate using a droplet ejection process, including the steps of (a) forming a recess section for disposing a functional fluid in the predetermined area so that the predetermined area has a first region, a second region connected to the first region, and the third region connected to the second region, the second region having a narrower width than the first region and the third region, (b) ejecting to the first region the functional fluid containing a material for the wiring pattern, (c) drying the functional fluid ejected to the first region to form a first film, (d) ejecting the functional fluid to the third region, and (e) drying the functional fluid ejected to the third region to form a second film.

According to this aspect of the invention, since the step of forming the wiring pattern by ejecting the functional fluid to the recess section corresponding to the predetermined area on the substrate includes the step of forming the recess section, the first film forming step of ejecting the functional fluid to the first region and then drying the functional fluid, and the second film forming step of ejecting the functional fluid to the third region and then drying the functional fluid, the functional fluid ejected to be disposed to the first region flows into the second region having a narrower width than the first region by the capillary phenomenon, and is then solidified. And similarly, the functional fluid ejected to be disposed to the third region flows into the second region having a narrower width than the third region by the capillary phenomenon, and is then solidified. And thus, the second region is filled with the solidified functional fluid. Since the second region filled with the functional fluid is the gate electrode, the number of occurrences of insufficient film thickness or breaking patterns can be reduced. Therefore, the wiring pattern having a little quality problems and superior electrical characteristics can be formed.

In the method of forming a wiring pattern according to another aspect of the invention, a bank for surrounding the predetermined area is preferably formed on the substrate.

According to this aspect of the invention, since the recess section is defined by the bank, the functional fluid ejected to the predetermined area easily flows into the recess section.

In the method of forming a wiring pattern according to another aspect of the invention, a part of the wiring pattern formed on the predetermined area corresponding to the second region preferably forms a gate electrode.

According to this aspect of the invention, since the functional fluid is apt to be accumulated in the second region in the help of the capillary phenomenon, the film thickness in the second region can easily be made even, thus occurrence of the insufficient film thickness or breaking patterns of the gate electrode as the second region can be reduced.

In the method of forming a wiring pattern according to another aspect of the invention, the third region preferably has a shape including a circular arc in a part of the outer periphery.

According to this aspect of the invention, since the third region has a shape including a circular arc in a part of outer periphery, the functional fluid ejected to the third region is easily accumulated, thus the accumulated functional fluid can easily flow from the third region toward the second region in the help of the capillary phenomenon.

In the method of forming a wiring pattern according to still another aspect of the invention, the wiring pattern includes a plurality of films different from each other disposed in the recess section, each of the films corresponding to a pair of the first and the second films, and the first ejection step, the first film forming step, the second ejection step, and the second film forming step are executed for each of the films to stack the films.

According to this aspect of the invention, since the first and second ejection steps and the first and second film forming steps are provided, and the first and the second films are formed for each of the plurality of films, a multi-layered wiring pattern composed of different films can be provided.

A method of manufacturing a device according to another aspect of the invention is a method of manufacturing a device having a wiring pattern formed in a predetermined area on the substrate using a droplet ejection process including the step of forming the wiring pattern on the substrate using the method of forming a wiring pattern according to the aspect of the invention.

According to this aspect of the invention, since the wiring pattern having a little quality problems such as insufficient film thickness or breaking patterns and superior in the electric characteristics, the wiring resistance becomes substantially even, thus the device hardly degraded in pixel driving performance can be provided.

In the method of manufacturing a device according to still another aspect of the invention, the gate electrode and the gate wiring are preferably formed on the substrate as the wiring pattern.

According to this aspect of the invention, since the wiring resistance becomes even by forming the film to have a substantially even thickness in the gate electrode and the gate wiring, the device hardly degraded in the pixel driving performance and superior in the electric characteristics can be provided.

A wiring pattern according to still another aspect of the invention is a wiring pattern formed in a predetermined area on the substrate using a droplet ejection process, the predetermined area including a first region, a second region connected to the first region, a third region connected to the second region, and having a shape narrower in the second region than in the first region and the third region, including a first film formed in the first region and the second region by ejecting the functional fluid to the first region and drying the functional fluid, and a second film formed in the second region and the third region by ejecting the functional fluid to the third region and then drying the functional fluid.

According to this aspect of the invention, in forming the wiring pattern by ejecting the functional fluid to the recess section corresponding to the predetermined area on the substrate, the functional fluid ejected to be disposed to the first region flows into the second region having a narrower width than the first region by the capillary phenomenon, and is then solidified. And similarly, the functional fluid ejected to be disposed to the third region flows into the second region having a narrower width than the third region by the capillary phenomenon, and is then solidified. And thus, the second region is filled with the solidified functional fluid. Since the second region filled with the functional fluid is the gate electrode, the number of occurrences of insufficient film thickness or breaking patterns can be reduced. Therefore, the wiring pattern having a little quality problems and superior electrical characteristics can be provided.

In the wiring pattern according to another aspect of the invention, the recess section provided on the substrate is preferably defined by a bank surrounding the predetermined area.

According to this aspect of the invention, since the recess section is defined by the bank, the functional fluid ejected to the predetermined area easily flows into the recess section.

In the wiring pattern according to another aspect of the invention, a part of the wiring pattern formed on the predetermined area corresponding to the second region preferably forms a gate electrode.

According to this aspect of the invention, since the functional fluid is apt to be accumulated in the second region in the help of the capillary phenomenon, the film thickness in the second region can easily be made even, thus occurrence of the insufficient film thickness or breaking patterns of the gate electrode as the second region can be reduced.

In the wiring pattern according to another aspect of the invention, the third region preferably has a shape including a circular arc in a part of the outer periphery.

According to this aspect of the invention, since the third region has a shape including a circular arc in a part of outer periphery, the functional fluid ejected to the third region is easily accumulated, thus the accumulated functional fluid can easily flow from the third region toward the second region.

In the wiring pattern according to still another aspect of the invention, the wiring pattern includes a plurality of films different from each other and disposed in the recess section, the films each corresponding to a pair of the first and the second films are preferably stacked each other.

According to this aspect of the invention, since the first and second films are provided, and the first and the second films are formed for each of the plurality of films, a multi-layered wiring pattern composed of different films can be provided.

A device according to still another aspect of the invention includes a substrate and the wiring pattern according to the above aspect of the invention formed on the substrate.

According to this aspect of the invention, since the wiring pattern described above having the wiring resistance substantially even is equipped, the device hardly degraded in the pixel driving performance and superior in the electric characteristics can be provided.

In the device according to still another aspect of the invention, the gate electrode and the gate wiring are preferably provided on the substrate as the wiring pattern.

According to this aspect of the invention, since the wiring resistance becomes even by forming the film to have a substantially even thickness in the gate electrode and the gate wiring, the device hardly degraded in the pixel driving performance and superior in the electric characteristics can be provided.

An electro-optic device according to still another aspect of the invention includes the device according to the above aspect of the invention.

According to this aspect of the invention, since the device hardly degraded in the pixel driving performance and having superior electrical characteristics is equipped, stable transistor performance can be obtained. And, an electro-optic device capable of improving the quality or the performance can be provided. Note that the electro-optic device includes and collectively means, for example, those converting electrical energy to optical energy in addition to those having an electro-optic effect for altering transmission of light by changing the reflection index of a substance in accordance with the electric field. Specifically, a liquid crystal display device using the liquid crystal as an electro-optic substance, an organic EL device using the organic EL (Electroluminescence), an inorganic EL device using the inorganic EL, a plasma display device using a plasma gas as the electro-optic substance, and so on can be cited. Further, an electrophoretic display device (EPD), a field emission display device (FED), and so on can also be cited.

An electronic instrument according to still another aspect of the invention includes the electro-optic device according to the above aspect of the invention.

According to this aspect of the invention, since the electro-optic device capable of improving the quality or the performance is equipped, the electronic instrument capable of further improving the quality can be provided.

### BRIEF DESCRIPTION OF THE DRAWINGS

The invention will now be described with reference to the accompanying drawings, wherein like numbers refer to like elements.

FIG. 1 is a perspective view showing a schematic configuration of a droplet ejecting device IJ according to an embodiment.

FIG. 2 is a schematic cross-sectional view for explaining the principle of ejection of a liquid material using a piezoelectric method.

FIG. 3 is a plan view showing a schematic configuration of a substantial part of a TFT allay substrate.

FIG. 4A is a cross-sectional view of a TFT, and FIG. 4B is a cross-sectional view of a planar intersection between the gate wiring and the source wiring.

FIG. 5 is a flowchart showing a method of forming a wiring pattern.

FIGS. 6A through 6H are schematic views for showing an example of a procedure of forming a wiring pattern, wherein FIGS. 6A, 6C, 6E, and 6G are plan views, FIG. 6B is a schematic cross-sectional view showing a cross-sectional structure along the C-C line in FIG. 6A, FIG. 6D is a schematic cross-sectional view showing a cross-sectional structure along the C-C line in FIG. 6C, FIG. 6F is a schematic cross-sectional view showing a cross-sectional structure along the C-C line in FIG. 6E, FIG. 6H is a schematic cross-sectional view showing a cross-sectional structure along the C-C line in FIG. 6G.

FIGS. 7A through 7F are schematic views for showing the example of a procedure of forming a wiring pattern, wherein FIGS. 7A, 7C, and 7E are plan views, FIG. 7B is a schematic cross-sectional view showing a cross-sectional structure along the C-C line in FIG. 7A, FIG. 7D is a schematic cross-sectional view showing a cross-sectional structure along the C-C line in FIG. 6C, and FIG. 7F is a schematic cross-sectional view showing a cross-sectional structure along the C-C line in FIG. 6E.

FIGS. 8A and 8B are schematic views showing a schematic structure of a wiring pattern, wherein FIG. 8A is a plan view, and FIG. 8B is a schematic cross-sectional view showing a cross-sectional structure along the C-C line in FIG. 8A.

FIG. 9 is a schematic structural view of a plasma processing device.

FIG. 10 is a plan view of a liquid crystal display device seen from an opposing substrate.

FIG. 11 is a cross-sectional view along the H-H′ line of FIG. 10.

FIG. 12 is a circuit diagram of an equivalent circuit of the liquid crystal display device.

FIG. 13 is a perspective view of a mobile phone as an electronic instrument.

### DESCRIPTION OF THE EMBODIMENTS

Hereinafter, some embodiments of a method of forming a thin film pattern, a method of manufacturing a device, the device, an electro-optic device, and an electronic instrument according to the invention will be cited and explained in detail with reference to the accompanying drawings.

### Embodiments

As the resent embodiment, an example of a case is explained in which a functional fluid X containing conductive fine particles is ejected as droplets from a nozzle of a droplet ejection head 1 using a droplet ejection process, thereby forming a wiring pattern formed of a number of conductive films in a bank formed on a substrate in accordance with the wiring pattern. Here at first, prior to explaining a distinguishing structure and method of the invention, a functional fluid for a wiring pattern, a substrate, a droplet ejection method, a droplet ejection device used for the droplet ejection process will sequentially be explained.

Wiring Pattern Functional Fluid

The wiring pattern functional fluid X is composed of a dispersion liquid containing conductive fine particles dispersed in a dispersion medium. In the present embodiment, metal fine particles including either one of, for example, gold, silver, cupper, iron, chromium, manganese, molybdenum, titanium, palladium, tungsten, and nickel, or oxides thereof, fine particles of electrically conductive polymers or superconductive materials can be used as the electrically conductive fine particles. In order to enhance dispersibility, these conductive fine particles can be used with organic matters coated on the surfaces. The particle sizes of the conductive fine particles are preferably no smaller than 1.0 nm and no greater than 0.1 μm. If the particle sizes are greater than 0.1 μm, clogging may occur in the ejection nozzle of the droplet ejection head described below. Further, if it is smaller than 1 nm, the volume ratio of the coating agent with respect to the conductive fine particles becomes larger, thus the ratio of the organic matters in the resulting film becomes too large.

The dispersion medium is not limited providing it can disperse the electrically conductive fine particles described above and does not cause any agglutinations. For example, other than water, alcohol such as methanol, ethanol, propanol, or butanol, carbon hydride compounds such as n-heptane, n-octane, decane, dodecane, tetradecane, toluene, xylene, cymene, durene, indene, dipentene, tetrahydronaphthalene, decahydronaphthalene, or cyclohexylbenzene, etherates such as ethyleneglycoldimethylether, ethylene glycoldiethylether, ethylene glycolmethylethylether, diethyleneglycoldimethylether, diethyleneglycoldiethylether, diethyleneglycolmethylethylether, 1,2-dimethoxyethane, bis(2-methoxyethyl)ether, or p-dioxane, and further polar compounds such as propylene carbonate, ã-butyrolactone, N-nethyl-2-pyrrolidone, dimethylformamide, dimethylsulfoxide, or cyclohexanone can be exemplified. In the above compounds, in view of dispersibility of the fine particles and stability of the dispersion liquid, further facility of applying to the droplet ejection method, water, alcohol, carbon hydride compounds, and etherates are preferable, and as a more preferable dispersion medium, water and carbon hydride compounds can be cited.

The surface tension of the dispersion liquid of the conductive fine particles is preferably in a range of no less than 0.02N/m and no greater than 0.07N/m. When the fluid is ejected using the droplet ejection process, the surface tension of less than 0.02N/m easily causes the curved flight because the wettability of the ejection nozzle surface to the compositions of the wiring pattern functional fluid X is increased, on the one hand, and the surface tension of greater than 0.07N/m makes it difficult to control the ejection amount or the ejection timing because the shape of the meniscus in the ejection nozzle tip is not stabilized, on the other hand. In order for adjusting the surface tension, a minute amount of surface tension adjustment agent such as a fluorinated agent, a silicone agent, or a nonionic agent is preferably added to the dispersion liquid as long as the contact angle with the substrate is not substantially decreased. The nonionic surface tension adjustment agent enhances wettability of the substrate to the fluid, improves the leveling property of the film, and works for preventing microscopic unevenness of the film from occurring. The surface tension adjustment agent can include an organic compound such as alcohol, ether, ester, or ketone, if necessary.

The viscosity of the dispersion liquid is preferably in a range of no less than 1 mPa·s and no greater than 50 mPa·s. When the liquid material is ejected as the droplets using the droplet ejection process, the viscosity of less than 1 mPa·s easily causes contamination in the periphery of the nozzle with the outflow of the wiring pattern functional fluid, and the viscosity of greater than 50 mPa·s increases the frequency of the clogging in the nozzle hole, thus making the smooth ejection of the droplets difficult.

Substrate

As the substrate to which the wiring pattern is provided, various kinds of materials such as glass, quartz glass, a Si wafer, a plastic film, or a metal plate can be used. Further, the surface of each of the substrates formed of the various materials can be provided with a semiconductor film, a metal film, a dielectric film, or an organic film as a foundation layer.

Droplet Ejection Process

Note that, as an ejection technology used for the droplet ejection process, the charge control method, the pressure vibration method, electromechanical conversion method, electrothermal conversion method, electrostatic absorption method, and so on can be cited. In the charge control method, the material is charged by a charge electrode and ejected from an ejection nozzle while its flight orientation is controlled by a deflection electrode. Further, in the pressure vibration method, the material is ejected from the tip of the ejection nozzle by being applied with very high pressure of about 30 kg/cm², and when no control voltage is applied, the material is forwarded straight to be ejected from the ejection nozzle, and when the control voltage is applied, an electrostatic repelling force is generated in the material to cause the material to fly in various directions and not to be ejected from the ejection nozzle. Further, in the electromechanical conversion method, the characteristics of the piezoelectric element that distorts in response to a pulsed electric signal are utilized, and when the piezoelectric element distorts, pressure is applied to a chamber containing the material via an elastic member to push the material out of the chamber to eject it from the ejection nozzle.

Further, in the electrothermal conversion method, the material is rapidly vaporized to generate a bubble by a heater provided in a chamber containing the material, and the material in the chamber is ejected by a pressure caused by the bubble. In the electrostatic absorption method, minute pressure is applied to a chamber containing the material to form a meniscus at the ejection nozzle, and then electrostatic absorption force is applied in this condition to take the material out of the nozzle. Other than the above methods, a method utilizing viscosity alteration of fluid by electric field or a method for flying the material by discharge sparks can also be adopted. The droplet ejection method has advantages that there is little waste in using the material and that a desired amount of material can precisely be disposed on a desired position. Note that the weight of one droplet of the liquid material ejected by the droplet ejection method is, for example, 1 through 300 nanograms.

Device manufacturing equipment used for manufacturing the device according to the embodiment of the invention will hereinafter be explained. As the device manufacturing equipment, a droplet ejection device for manufacturing the device by ejecting (dropping) droplets from the droplet ejection head to the substrate is used.

Droplet Ejection Device

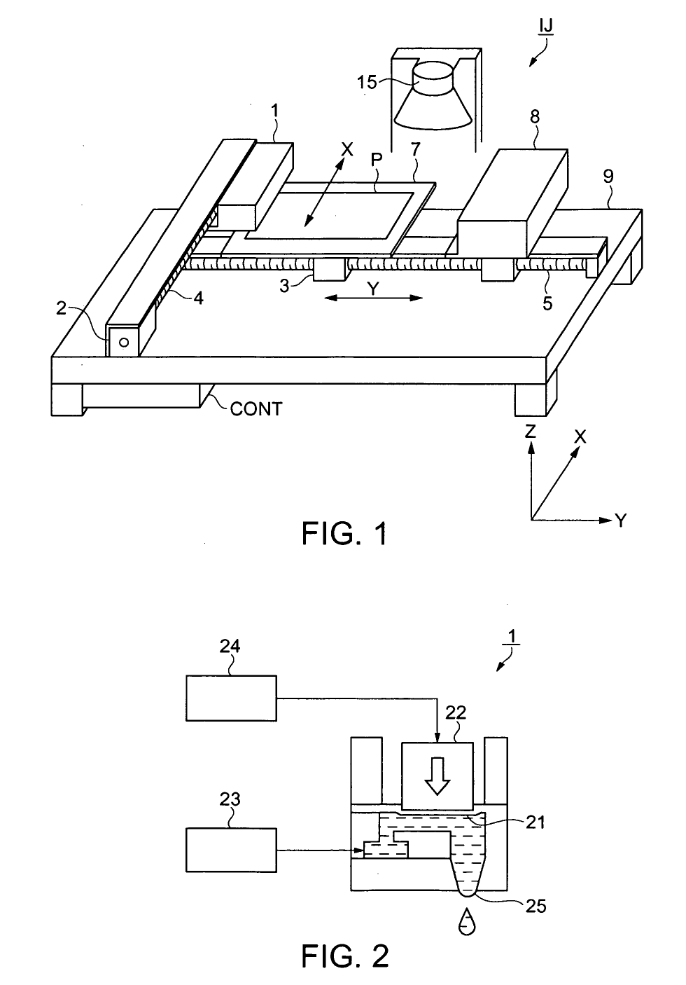

FIG. 1 is a perspective view schematically showing the configuration of the droplet ejection device IJ. The droplet ejection device IJ is equipped with the droplet ejection head 1, an X axis direction drive shaft 4, a Y axis direction guide shaft 5, a control device CONT, a stage 7, a cleaning mechanism 8, a base member 9, and a heater 15.

The stage 7 is for supporting the substrate P to which the wiring pattern functional fluid X is disposed by the droplet ejection device IJ, and is equipped with a fixing mechanism not shown for fixing the substrate P to a reference position.

The droplet ejection head 1 is a multi-nozzle type droplet ejection head equipped with a number of ejection nozzles, and the longitudinal direction thereof is conformed to the X axis direction. The number of ejection nozzles are provided to the lower surface of the droplet ejection head 1 so as to be aligned in the X axis direction with a constant interval. The wiring pattern functional fluid X containing the conductive fine particles described above is ejected from the ejection nozzles of the droplet ejection head 1 to the substrate P supported by the stage 7.

An X axis direction drive motor 2 is connected to the X axis direction drive shaft 4. The X axis direction drive motor 2 is, for example, a stepping motor, and rotates the X axis direction drive shaft 4 when a drive signal of the X axis direction is supplied from the control device CONT. In response to the rotation of the X axis direction drive shaft 4, the droplet ejection head 1 moves in the X axis direction.

The Y axis direction guide shaft 5 is fixed to the base member 9 so as not to move therefrom. The stage 7 is equipped with a Y axis direction drive motor 3. The Y axis direction drive motor 3 is, for example, a stepping motor, and moves the stage 7 in the Y axis direction when a drive signal of the Y axis direction is supplied from the control device CONT.

The control device CONT supplies the droplet ejection head 1 with a voltage for controlling ejection of the droplet L. Further, the control device CONT supplies the X axis direction drive motor 2 with the drive pulse signal for controlling movement of the droplet ejection head 1 in the X axis direction, and at the same time, it supplies the Y axis direction drive motor 3 with the drive pulse signal for controlling movement of the stage 7 in the Y axis direction.

The cleaning mechanism 8 is for cleaning the droplet ejection head 1, and is equipped with a Y axis direction drive motor not shown in the drawings. By driving the Y axis direction drive motor, the cleaning mechanism 8 moves along the Y axis direction guide shaft 5. The movement of the cleaning mechanism 8 is also controlled by the control device CONT.

The heater 15 here is means for thermal-treating the substrate P by a lamp anneal process, and performs evaporation of the solvent contained in the wiring pattern functional fluid X coated on the substrate P to dry the fluid. The control device CONT also controls powering on or off of the heater 15.

The droplet ejection device IJ ejects the droplets L to the substrate P while scanning the droplet ejection head 1 relatively to the stage 7 supporting the substrate P. Here, in the description below, it is assumed that the Y axis direction is the scanning direction and the X axis direction perpendicular to the Y axis direction is the non-scanning direction. Therefore, the ejection nozzles of the droplet ejection head 1 are provided so as to be aligned in the X axis direction, the non-scanning direction, with a constant interval. Note that, although the droplet ejection head 1 is aligned perpendicular to the moving direction of the substrate P in FIG. 1, the angle of the droplet ejection head 1 can be adjusted so that it traverses the moving direction of the substrate P. By thus arranged, the nozzle pitch can be adjusted by altering the angle of the droplet ejection head 1. Further, the distance between the substrate P and the surface provided with the nozzles can be arranged to be adjustable in accordance with a desire.

FIG. 2 is a schematic view for explaining the principle of ejecting the liquid material according to the piezoelectric method. In FIG. 2, piezoelectric elements 22 are disposed adjacent to a fluid chamber 21 for containing the liquid material (the wiring pattern functional fluid). The liquid material is supplied to the fluid chamber 21 via a liquid material supply system 23 including a material tank for containing the liquid material. The piezoelectric element 22 is connected to a drive circuit 24, and by applying voltage to the piezoelectric element 22 via the drive circuit 24 to distort the piezoelectric element 22, the fluid chamber is also distorted to eject the liquid material from the ejection nozzle 25 as the droplet L. In this case, an amount of distortion of the piezoelectric element 22 can be controlled by altering the value of the applied voltage. Further, the velocity of distortion of the piezoelectric element 22 can be controlled by altering the frequency of the applied voltage. Since no substantial heat is applied to the material in ejecting droplets in the piezoelectric method, an advantage that the composition of the material is hardly affected is obtained.

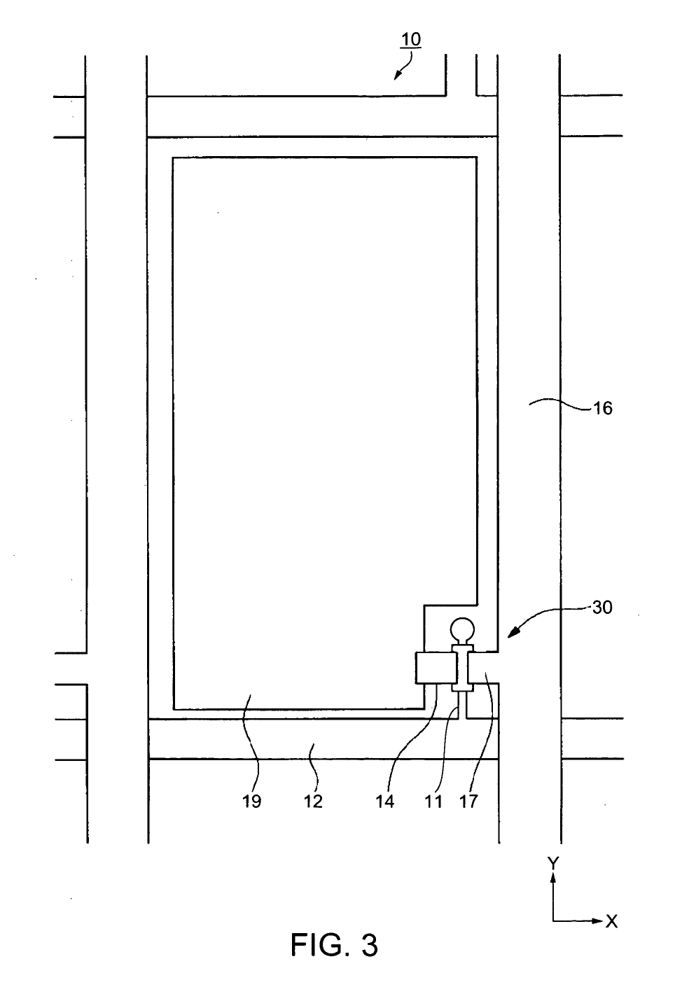

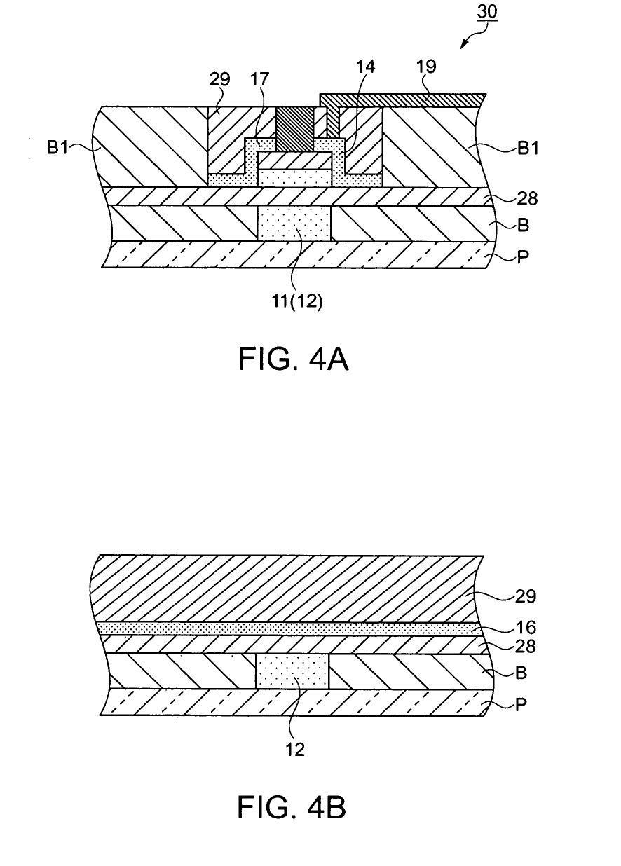

Hereinafter, a thin film transistor (TFT), an example of a device manufactured by using the wiring pattern forming method according to the present embodiment, will be explained. FIG. 3 is a plan view showing a schematic configuration of a part of a TFT array substrate including one TFT. FIG. 4A is a cross-sectional view of the TFT, and FIG. 4B is a cross-sectional view of a planar intersection between the gate wiring and the source wiring.

As shown in FIG. 3, there are provided on the TFT array substrate 10 including the TFT 30 the gate wiring 12, the source wiring 16, a drain electrode 14, and a pixel electrode 19 electrically connected to the drain electrode 14. The gate wiring 12 is formed so as to extend in the X axis direction, and a part of the gate wiring 12 is formed so as to extend in the Y axis direction. And, the part of the gate wiring 12 extending in the Y axis direction is used as the gate electrode 11. Note that the width of the gate electrode 11 is arranged to be narrower than the width of the gate wiring 12. And, the gate wiring 12 is formed using the wiring pattern forming method of the present embodiment of the invention. Further, a part of a source wiring 16 formed so as to extend in the Y axis direction is formed as a wider area, which is used as a source electrode 17.

As shown in FIGS. 4A and 4B, the gate wiring 12 is formed between the banks B provided on the substrate P. The gate wiring 12 and the banks B is covered with an insulating film 28, on which the source wiring 16, the source electrode 17, the drain electrode 14, and the banks B1 are formed. The gate wiring 12 is insulated from the source wiring 16 by the insulating film 28, and the gate electrode 11 is insulated from the source electrode 17 and the drain electrode 14 by the insulating film 28. The source wiring 16, the source electrode 17, and the drain electrode 14 are covered with an insulating film 29.

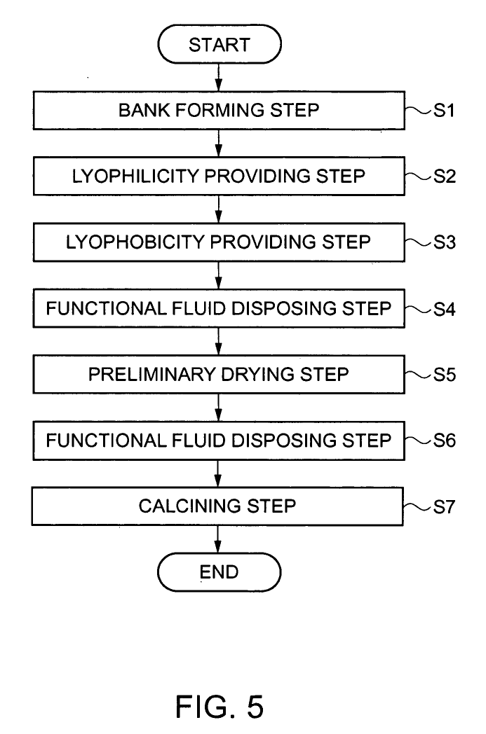

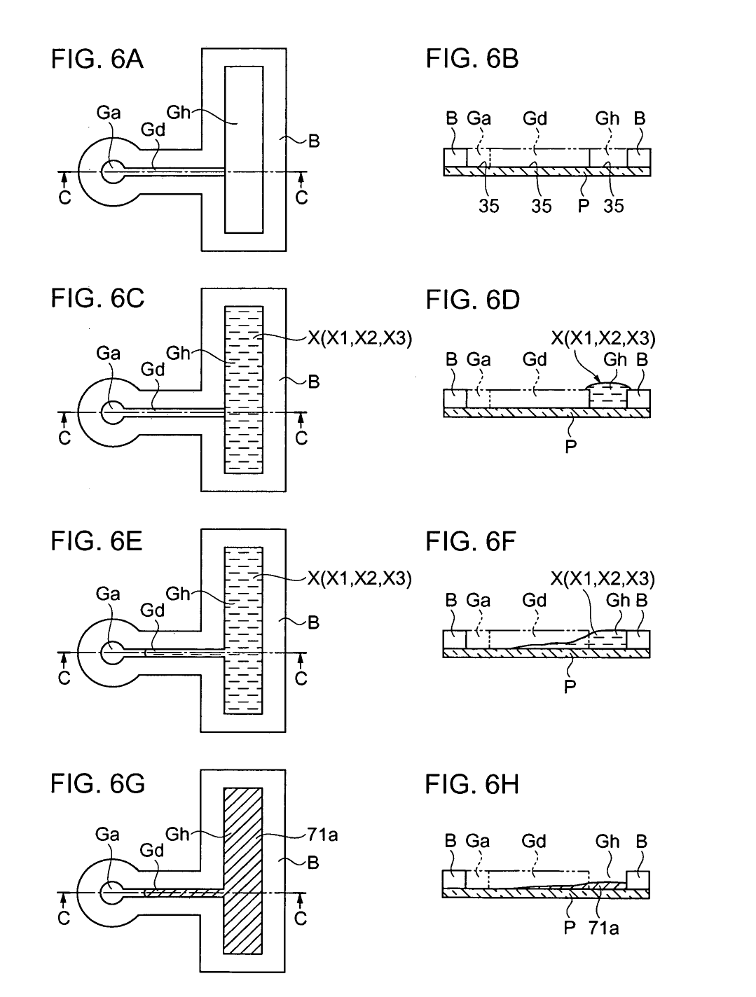

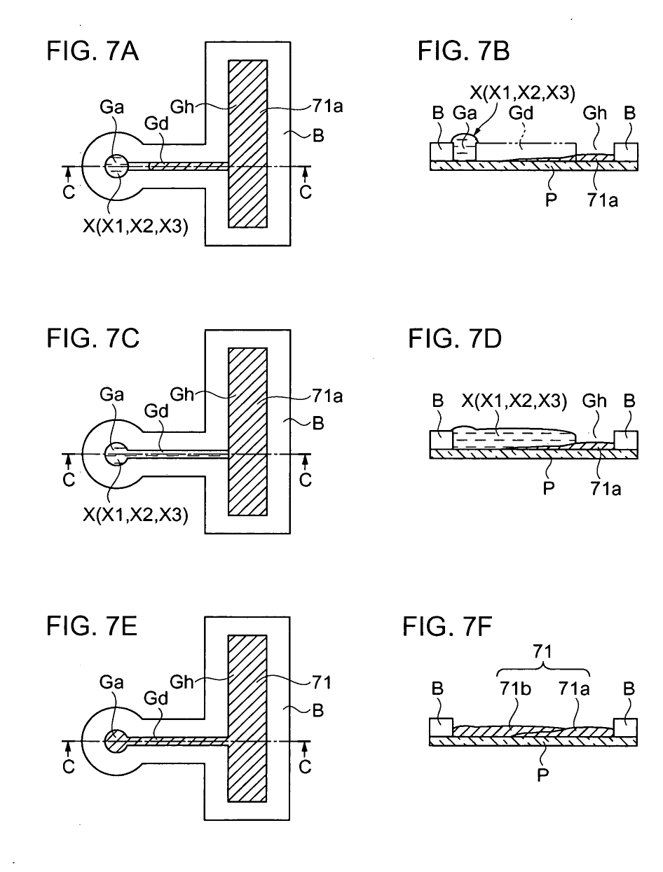

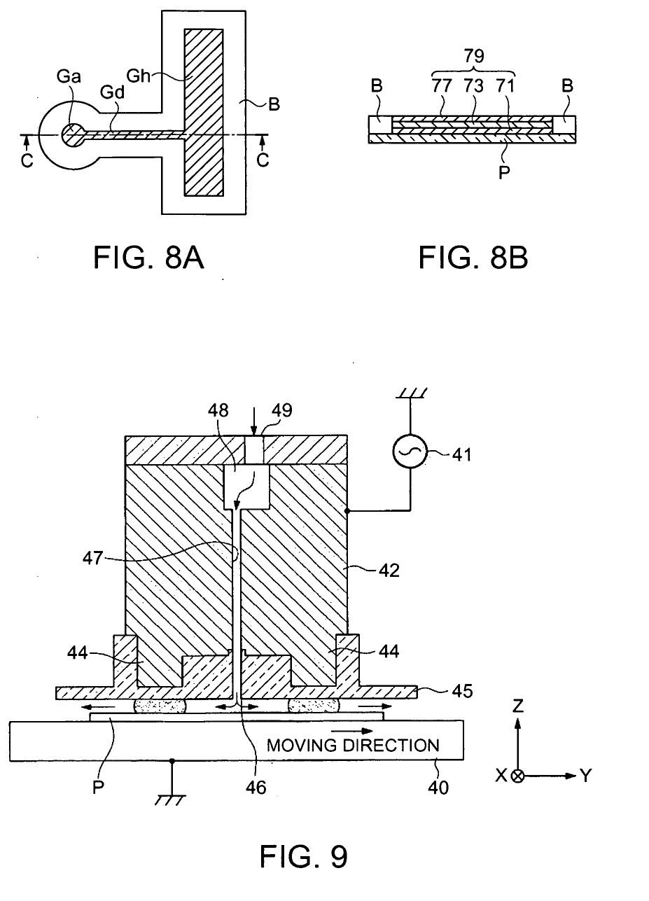

The wiring pattern forming method according to the present embodiment will hereinafter be described. FIG. 5 is a flowchart showing an example of the wiring pattern forming method according to the present embodiment. FIGS. 6A through 6H, and 7A through 7F are schematic views showing one example of a procedure of forming the wiring pattern. FIG. 8A is a plan view schematically showing the structure of the wiring pattern, and FIG. 8B is a schematic cross-sectional view showing the cross-sectional structure along the C-C line in FIG. 8A.

According to the wiring pattern forming method of the present embodiment, the wiring pattern functional fluid X is disposed on the substrate P to form the wiring film on the substrate P thereby forming the wiring pattern. The step S1 is a bank forming process for providing the banks B in a protruding manner on the substrate P for forming recess sections in accordance with the shape of the wiring pattern, the step S2 succeeding thereto is a lyophilicity providing process for providing the substrate P with lyophilicity, and the step S3 further succeeding thereto is a lyophobicity providing process for providing the surfaces of the banks B with lyophobicity. Further, the step S4 succeeding thereto is a functional fluid disposing process for disposing the wiring pattern functional fluid X on a first region in each of the banks B provided with lyophobicity, the step S5 succeeding thereto is a preliminary drying process for drying the wiring pattern functional fluid X to form a priming film 71, the step S6 is a functional fluid disposing process for disposing the wiring pattern functional fluid X on a third region, and the step S7, the final step, is a calcining process for thermal-treating the wiring pattern functional fluid X and the priming film 71.

Hereinafter, each process of the steps will be explained in detail. Note that the case will be explained here, in which the wiring pattern 79 of a multi-layered film composed of the priming film 71, a conductive film 73, and a diffusion preventing film 77 is formed on the substrate P. In the present embodiment, a glass substrate is used as the substrate P.

Firstly, the bank forming process of step S1 will be explained. In the bank forming process (step), an HMDS treatment is executed on the substrate P as a surface reformation treatment firstly prior to providing a bank B forming material. The HMDS treatment is executed by coating vapor form of hexamethyldisilazane ((CH₃)₃SiNHSi(CH₃)₃). Thus, the HMDS layer (omitted in the drawings) as an adhesive layer for enhancing adhesiveness of the bank B with the substrate P is formed on the substrate P.

The bank B is a member functioning as a separating member, and can be formed using a desired process such as a photolithography process or a printing process. If, for example, a photolithography process is used, the material for forming the bank B is coated on the substrate P using a predetermined process such as a spin costing process, a spray coating process, a roll coating process, a dye coating process, or a dip coating process so that the height thereof matches the height of the bank B to form a resist layer. And, the resist provided with a mask corresponding to the shape of the bank B (the shape of the wiring pattern) is exposed and then developed to leave the resist layer corresponding to the shape of the bank B. Finally, the material for forming the bank B in other areas than the mask area is removed by etching.

As shown in FIG. 6A, the first region Gh, the second region Gd, and the third region Ga as recess sections provided for disposing the wiring pattern functional fluid X are formed so as to be surrounded by the bank B. When the wiring pattern is formed, the first region Gh becomes the gate wiring 12, and similarly, the second region Gd becomes the gate electrode 11. The second region Gd is disposed to be connected to the first region Gh, and the third region Ga is disposed to be connected to one of the edges of the second region Gd. Further, the width of the first region Gh is made wider in comparison to the second region Gd. The width of the third region Ga is made wider than that of the second region Gd, and the third region Ga includes a section having a circular arc in the periphery.

As shown in FIG. 6B, the bank B is disposed on the substrate P and has a bottom section 35 composed of the bottom sections of the first region Gh, the second region Gd, and the third region Ga surrounded by the bank B.

In the wiring pattern forming method according to the present embodiment, an inorganic material is used as the material for forming the bank B. As a method of forming the bank B using an inorganic material, for example, a layer composed of the inorganic material can be formed on the substrate P using various coating processes, a CVD process (chemical vapor deposition process), or the like, followed by etching or ashing to pattern it thereby forming the bank B of a predetermined shape. Note that the bank B can be formed on a different substance form the substrate P, and then disposed on the substrate P.

As the material for forming the bank B, a material presenting lyophobicity with respect to the wiring pattern functional fluid X can be used, or as described below, an insulating organic material, which can be provided with lyophobicity (can be fluorinated) by a plasma process, has good adhesiveness with the base substrate, and can be easily patterned by a photolithography process, can also be used. As the inorganic material for forming the bank B, for example, a spin-on-glass film including either one of silica glass, alkylsiloxane polymer, alkylsilsesquioxane polymer, alkylsilsesquioxane hydride polymer, or polyarylether, a diamond film, a fluorinated amorphous carbon film, and so on can be cited. Further, as the inorganic material for forming the bank B, for example, aerogel, porous silica, and so on can also be used.

Note that an organic material can also be used as the material for forming the bank B. As the organic material for forming the bank B, a material presenting lyophobicity with respect to the wiring pattern functional fluid X can be used, or as described below, an insulating organic material, which can be provided with lyophobicity (can be fluorinated) by a plasma process, has good adhesiveness with the base substrate, and can be easily patterned by a photolithography process, can also be used. For example, a polymer material such as acrylic resin, polyimide resin, olefin resin, phenol resin, or melamine resin can be used. Alternatively, a material having an inorganic framework (siloxane bond) in the principal chain with an organic group attached thereto can also be used.

After forming the banks B on the substrate P, a hydrofluoric acid treatment is executed. The hydrofluoric acid treatment is a treatment for removing the HMDS layer (omitted from the drawings) surrounded by the bank B by etching with, for example, 2.5% hydrofluoric acid.

Then, the lyophilicity providing process of step S2 will be explained. In this lyophilicity providing step, the lyophilicity providing process for providing lyophilicity to the bottom 35 (the exposed section of the substrate P) surrounded by the bank B is executed. As the lyophilicity providing process, an ultraviolet (UV) irradiation process for exposing to ultraviolet radiation, an O₂ plasma process using oxygen as a process gas in the atmospheric conditions, or the like can selectively be used. In the present embodiment, the O₂ plasma process is executed.

In the O₂ plasma process, the substrate P is irradiated with oxygen in a plasma state discharged from a plasma discharge electrode. In an example of conditions of the O₂ plasma process, for example, the plasma power is in a range of 50 through 1000W, the flow rate of the oxygen gas is in a range of 50 through 100 mL/min, the relative moving velocity of the substrate P to the plasma discharge electrode is in a range of 0.5 through 10 mm/sec, and the temperature of the substrate is in a range of 70 through 90° C.

And, if the substrate P is a glass substrate whose surface is lyophilic with respect to the wiring pattern functional fluid X, the lyophilicity of the surface (the bottom 35) of the substrate P exposed in the area surrounded by the bank B can further be enhanced by executing the O₂ plasma process or the ultraviolet radiation process as in the present embodiment. Here, the O₂ plasma process or the ultraviolet radiation process is preferably executed so that the contact angle of the bottom section 35 surrounded by the bank with respect to the wiring pattern functional fluid X becomes no greater than 15 degrees.

FIG. 9 is a schematic view showing the configuration of an example of the plasma processing device used for executing the O₂ plasma process. The plasma process device shown in FIG. 9 includes an electrode 42 connected to an AC power supply 41 and a sample table 40, which is a grounding electrode. The sample table 40 is arranged to be able to move in the Y axis direction while supporting the substrate P. On the lower surface of the electrode 42, there are provided two parallel discharge generating sections 44 extended in the X axis direction perpendicular to the moving direction in protruded conditions, and a dielectric member 45 is also provided so as to surround the discharge generating sections 44. The dielectric member 45 is for preventing abnormal discharge in the discharge generating sections 44. And, the lower surface of the electrode 42 including the dielectric member 45 is substantially flat, and it is arranged that small gaps (the discharge gaps) are provided between the discharge generating sections 44 including the dielectric member 45 and the substrate P. Further, at the center of the electrode 42, there is provided a gas ejection port 46, which forms a part of a process gas supplying section formed as a shape elongated in the X axis direction. The gas ejection port 46 is connected to a gas introduction port 49 via a gas channel 47 and an intermediate chamber 48 inside the electrode.

A predetermined gas including the process gas ejected from the gas ejection port 46 through the gas channel 47 flows in the gap while being separated into two directions, the forward direction and the backward direction with respect to the moving direction (the Y axis direction), and is exhausted to the outside from the front end and back end of the dielectric member 45. At the same time, a predetermined voltage is applied to the electrode 42 from the AC power supply 41, and gaseous discharge occurs between the discharge generating sections 44 and the sample table 40. And, the plasma generated by the gaseous discharge generates active species of the predetermined gas in the excited state to continuously process the whole surface of the substrate P passing through the discharge area.

In the present embodiment, the predetermined gas is a mixture of oxygen (O₂) as a process gas and a noble gas such as helium (He) or argon (Ar) or an inactive gas such as nitrogen (N₂) for easily beginning and stably maintaining discharge under pressure nearly equal to the atmospheric pressure. In particular, by using oxygen as the process gas, residual dross of organic matters (the resist or the HMDS) generated in the bottom 35 of the bank B when forming the bank can be removed. In other words, there are some cases in which the HMDS (an organic matter) of the bottom section 35 surrounded by the bank B is not completely removed by the treatment with hydrofluoric acid described above. Or, in some cases, the resist (an organic matter) used for forming the bank B remains on the bottom 35 of the area surrounded by the bank B. Therefore, by executing the O₂ plasma process, the residual dross on the bottom 35 surrounded by the bank B can be removed.

Note that, although the description reads here that the HMDS layer (omitted from the drawings) is removed by executing the hydrofluoric acid treatment, the hydrofluoric acid treatment can be omitted because the HMDS layer (omitted from the drawings) at the bottom section 35 surrounded by the bank B is fully removed by the O₂ plasma process or the ultraviolet radiation process. Further, although the description reads here that either one of the O₂ plasma process and the ultraviolet radiation process is executed as the lyophilicity providing process, both of the O₂ plasma process and the ultraviolet radiation process can obviously be executed in combination.

Then, the lyophobicity providing process of step S3 will be explained. In the lyophobicity providing step, a lyophobicity providing process is executed on the bank B to provide lyophobicity to the surface thereof. As the lyophobicity providing process, a plasma process method (CF₄ plasma process method) using tetrafluoromethane as the process gas is adopted. In an example of conditions of the CF₄ plasma process, for example, the plasma power is in a range of 50 through 1000W, the flow rate of the tetrafluoromethane gas is in a range of 50 through 100 mL/min, the relative movement speed of the base body to the plasma discharge electrode is in a range of 0.5 through 20 mm/sec, and the temperature of the base body is in a range of 70 through 90° C. Note that the process gas is not limited to tetrafluoromethane, but other fluorocarbon gases or a gas such as SF₆, SF₅, or CF₃ can also be used as the process gas. In the CF₄ plasma process, the plasma processing device explained above with reference to FIG. 9 can be used.

By executing such a lyophobicity providing process, the bank B is provided with fluoric groups introduced in the resin forming the bank, thus high lyophobicity is provided to the bank B. Note that, although the O₂ plasma process as the lyophilicity providing process described above can be executed prior to formation of the bank B, the O₂ plasma process is preferably executed after the bank B has been formed because of the nature of being more easily fluorinated (provided with lyophobicity) with a pretreatment with O₂ plasma.

Note also that, although the lyophobicity providing process for the bank B slightly affects the lyophilicity of the exposed section of the substrate P surrounded by the bank B, which has previously been treated to have lyophilicity, particularly in case the substrate P is made of glass or the like, the lyophilicity (wettability, in other words) of the substrate P is practically maintained because no adoption of fluoric groups occurs during the lyophobicity providing process.

It is regarded that the surface reformulation treatment for providing the bank B with higher lyophobicity than the lyophobicity of the bottom section 35 surrounded by the bank B by the lyophilicity providing process and the lyophobicity providing process described above. Note that, although the O₂ plasma process is executed here as the lyophilicity providing process, since the introduction of fluoric groups caused by the lyophobicity providing process does not occur with the substrate made of glass or the like, as described above, the bank B can be provided with higher lyophobicity than the bottom section 35 surrounded by the bank B by executing only the CF₄ plasma process without executing the O₂ plasma process. The condition of the bank B before the wiring pattern functional fluid X is disposed thereon is shown in FIGS. 6A and 6B.

Then, the functional fluid disposing process of step S4 will now be explained. In the functional fluid disposing step, the wiring pattern functional fluid X is disposed on the area of the substrate P surrounded by the bank B using the droplet ejection process by the droplet ejection device IJ described above. In the functional fluid disposing process, the wiring pattern functional fluid X containing the wiring pattern forming material is ejected from the droplet ejection head 1 as forms of droplets L. Using the droplet ejection process by the droplet ejection device IJ, the wiring pattern function fluid X for forming the priming film 71 is disposed in the first region Gh as shown in FIGS. 6C and 6D. And, as shown in FIGS. 6E and 6F, a part of the wiring pattern functional fluid X disposed on the first region Gh flows in the second region Gd by the capillary phenomenon. Note that the wiring pattern functional fluid X (X1) for forming the priming film 71 uses manganese as a material for forming the priming film 71 and diethyleneglycoldiethylether as the solvent (dispersion medium).

In the present embodiment, the ambient atmosphere for ejecting the droplets L is preferably set to have temperature of no higher than 60° C. and moisture of no higher than 80%. Thus, more stable droplet ejection can be executed without any clogging in the ejection nozzles 25 of the droplet ejection head 1.

Then, the preliminary drying process of step S5 will now be explained. In the preliminary drying step, a drying process is executed in order for removing the dispersion medium and for assuring the film thickness as needed after the wiring pattern functional fluid X (X1) is disposed. The drying process can be executed by, for example, an ordinary hot plate for heating the substrate P, a process using an electrical heating furnace, or lamp annealing. A light source for the lamp annealing process is not particularly limited, but an infrared lamp, a xenon lamp, a YAG laser, an argon laser, a carbon oxide gas laser, or excimer laser using XeF, XeCl, XeBr, KrF, KrCl, ArF, or ArCl can be used as the light source. The light sources having an output power of no less than 10W and no greater than 5000W can generally be used, but in the present embodiment, those of no less than 100W and no greater than 1000W are sufficient. As shown in FIGS. 6G and 6H, by preliminarily drying the wiring pattern functional fluid X (X1), a first film 71a is formed in the first region Gh and a part of the second region Gd.

Then, the functional fluid disposing process of step S6 will now be explained. In the functional fluid disposing step, as shown in FIGS. 7A and 7B, when the wiring pattern functional fluid X (X1) is disposed on the third region Ga, the wiring pattern functional fluid X (X1) disposed on the third region Ga flows into the second region Gd by the capillary phenomenon as shown in FIGS. 7C and 7D.

Then, the calcining process of step S7 will now be explained. In the calcining step, a thermal treatment for removing the dispersion medium in the wiring pattern functional fluid X (X1) and for assuring the film thickness is executed. Further, if the surfaces of the metal particles are coated with organic substances or the like for enhancing dispersibility, the material coated thereon also needs to be removed. Therefore, a thermal treatment and/or a light treatment are executed on the substrate on which the ejection process is executed. The thermal treatment and/or the light treatment are usually executed in the atmosphere, and can be executed in an inactive ambient gas such as nitrogen, argon, or helium, or a reducing ambient gas such as hydrogen if necessary. The process temperature of the thermal treatment and/or the light treatment is appropriately decided taking the boiling point (the vapor pressure) of the dispersion medium, the nature or pressure of the ambient gas, thermal behavior of the fine particles such as dispersibility or oxidation property, presence or absence or an amount of the coating material, an allowable temperature limit of the base member, and so on into consideration. In the present embodiment, a calcining process in the atmosphere using a clean oven at a temperature in a range of 280 through 300° C. for 300 minutes is executed on the wiring pattern functional fluid X forming the pattern. Note that, for example, the organo-silver compounds need to be baked at about 200° C. to remove the organic components. Further, in case of using a substrate made of plastic or the like, it is preferably executed at a temperature no lower than the room temperature and no higher than 250° C. By the steps described above, electrical contact between the fine particles is assured in the dried film executed through the ejection process, and the dried film is changed to be the conductive film. According to the above process, a second film 71b is formed in the third region Ga and a part of the second region Gd after the ejection process. As a result, as shown in FIGS. 7E and 7F, the priming film 71 as a first wiring pattern can be formed.

As shown in FIG. 8A, the area surrounded by the bank B is composed of the first region Gh, the second region Gd, and the third region Ga. Note that when the priming film 71 as the first wiring pattern is formed on the substrate P, the first region Gh becomes the gate wiring 12, and the second region Gd becomes the gate electrode 11. As shown in FIG. 8B, the wiring pattern 79 formed of a multi-layered film having a three layered structure is provided to the area surrounded by the bank B on the substrate P. The wiring pattern 79 is composed of the priming film 71 as the first wiring pattern, a conductive film 73 as the second wiring pattern, and a diffusion preventing film 77 as the third wiring pattern.

A method of forming the wiring pattern 79 of the multi-layered film having the three-layered structure will hereinafter be described. By executing the steps of S1 through S7 shown in FIG. 5, the priming film 71 as the first wiring pattern is formed on the substrate P. Then, the steps of S4 through S7 shown in FIG. 5 are repeated (FIGS. 6C through 6H, and 7A through 7F) to form the conductive film 73 as the second wiring pattern. Further, the steps of S4 through S7 shown in FIG. 5 are repeated (FIGS. 6C through 6H, and 7A through 7F) to form the diffusion preventing film 77 as the third wiring pattern. And, the wiring pattern 79 of the multi-layered film having the three-layered structure composed of the priming film 71, the conductive film 73, and the diffusion preventing film 77 stacked on the substrate P.

More specifically, an organo-silver compound is used as a conductive material for forming the conductive film 73 as the second wiring pattern, and diethyleneglycoldiethylether is used as the solvent (dispersion medium) for the wiring pattern functional fluid X (X2). In the functional fluid disposing process of step S4 shown in FIG. 5, the wiring pattern functional fluid X (X2) is ejected from the droplet ejection head 1 to be disposed in the first region Gh. The wiring pattern functional fluid X (X2) is dried in the preliminary drying process of step S5. Further, the wiring pattern functional fluid X (X2) is disposed in the third region Ga in the functional fluid disposing process of step S6, and then calcined in the calcining process of step S7. Thus, the conductive film 73 as the second wiring pattern is formed on the priming film 71 as the first wiring pattern.

Then, nickel is used as a diffusion preventing material for forming the diffusion preventing film 77 as the third wiring pattern, and diethyleneglycoldiethylether is used as the solvent (dispersion medium) for the wiring pattern functional fluid X (X3). In the functional fluid disposing process of step S4 shown in FIG. 5, the wiring pattern functional fluid X (X3) is ejected from the droplet ejection head 1 to be disposed in the first region Gh. The wiring pattern functional fluid X (X3) is dried in the preliminary drying process of step S5. Further, the wiring pattern functional fluid X (X3) is disposed in the third region Ga in the functional fluid disposing process of step S6, and then calcined in the calcining process of step S7. Thus, the diffusion preventing film 77 as the third wiring pattern is formed on the conductive film 73 as the second wiring pattern. And, the wiring pattern 79 of the multi-layered film having the priming film 71, the conductive film 73, and the diffusion preventing film 77 stacked on the substrate P to form the three-layered structure.

Note that the process for disposing the wiring pattern functional fluid X2 and the wiring pattern functional fluid X3 is the same as the process for disposing the wiring pattern functional fluid X1 described above. The wiring pattern functional fluid X2 disposed in the first region Gh from the droplet ejection head 1 flows into the second region Gd by the capillary phenomenon, and the film is formed by drying to solidify the functional fluid. Similarly, the wiring pattern functional fluid X3 disposed in the third region Ga flows into the second region Gd by the capillary phenomenon, and when the functional fluid is dried to be solidified, the film is formed.

According to the embodiment described above, the following advantages can be obtained.

The wiring pattern functional fluid X (X1) disposed in the first region Gh flows from the first region Gh toward the second region Gd by the capillary phenomenon, and by drying to solidify the functional fluid, the film is formed. Further, by providing the third region Ga, the wiring pattern functional fluid X (X1) disposed to the third region Ga flows into the second region Gd by the capillary phenomenon, and by drying to solidify the functional fluid, the film is formed. In this case, since the second region Gd is filled with a larger amount of the functional fluid, the gate electrode 11, which is the second region Gd, is formed to have a substantially even thickness. Moreover, since the number of insufficient film thicknesses and breaking patterns can be suppressed, the gate electrode 11 and the gate wiring 12 can be formed to have even film thicknesses. By forming the film with the even film thickness, the wiring resistance as the pattern becomes substantially even, thus the wiring pattern superior in electrical characteristics can be obtained.

Since the wiring pattern with superior electrical characteristics is obtained, the device capable of suppressing degradation in pixel driving performance can be obtained.

Since the device with excellent electrical characteristics is obtained, stable transistor performance can be obtained. Therefore, an electro-optic device and an electronic instrument capable of improving the quality or the performance can be provided.

Display Device (Electro-optic Device) and Manufacturing Method Thereof

Hereinafter, a liquid crystal display device 100, an embodiment of the electro-optic device according to the invention will be described. The liquid crystal display device 100 according to the preset embodiment is equipped with a TFT including circuit wiring formed using the method of forming a circuit wiring explained in the first embodiment.

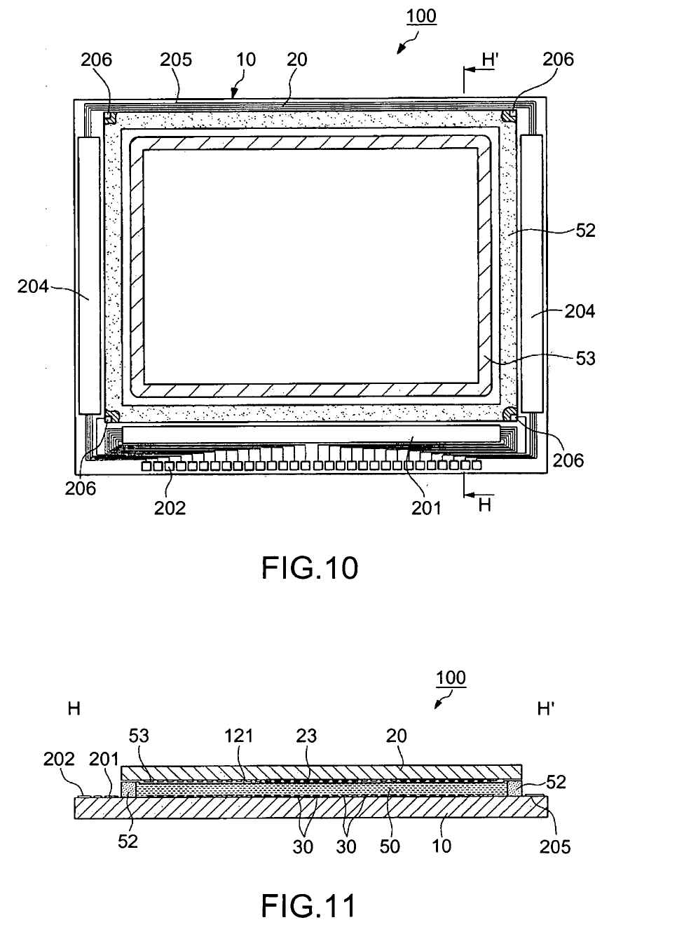

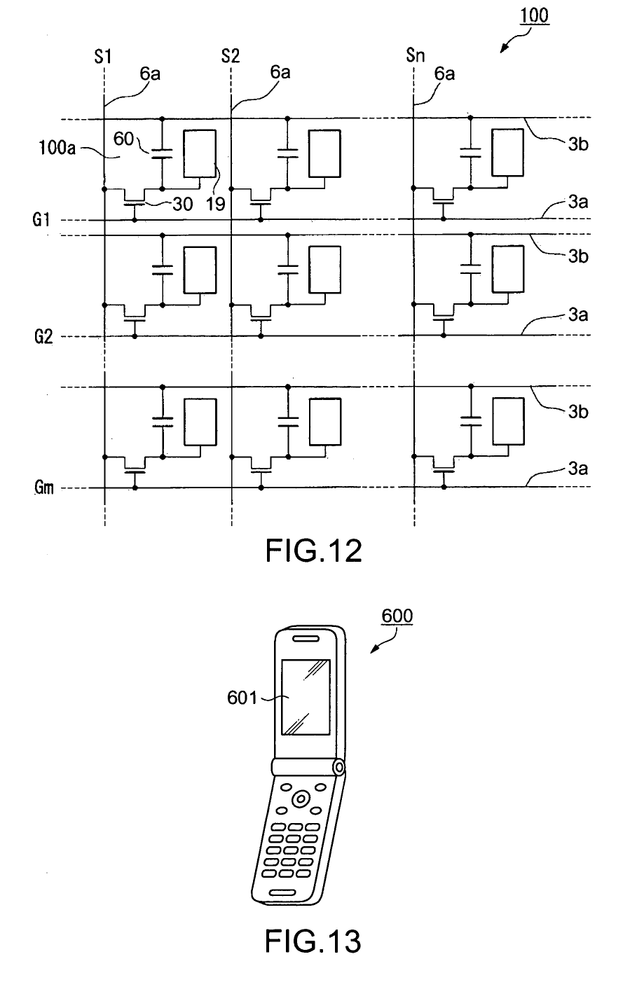

FIG. 10 is a plan view showing the liquid crystal display device 100 according to the embodiment of the invention together with various composing elements viewed from an opposing substrate, and FIG. 11 is a cross-sectional view along the H-H′ line shown in FIG. 10. FIG. 12 is an equivalent circuit diagram of various components, wiring, and so on in a number of pixels formed in a matrix in the image display area of the liquid crystal display device 100. Note that, in the drawings used in the following descriptions, a different scale is used for each of the layers or members in order for illustrating them in visible sizes in the drawings.

In FIGS. 10 and 11, the liquid crystal display device (electro-optic device) 100 according to an embodiment of the invention has a structure in which the TFT array substrate 10 and the opposing substrate 20 making a pair are adhered to each other with a seal member 52, the light curing sealant, and the liquid crystal 50 is encapsulated and held in the region partitioned with the seal member 52. The seal member 52 is formed in the surface of the substrate as a closed frame.

In the inner area of the area in which the sealing member 52 is formed, there is provided a periphery cover 53 made of a light blocking material. In the outer area of the sealing member 52, there are provided a data line drive circuit 201 and mounting terminals 202 along one side of the TFT array substrate 10, and scanning line drive circuits 204 are formed along two sides adjacent to the one side. In the remaining side of the TFT array substrate 10, there are provided a number of wiring 205 for connecting the scanning line drive circuits 204 provided on the both sides of the image display area. Further, on at least one corner of the opposing substrate 20, there is provided an inter-substrate connecting member 206 for achieving electrical conduction between the TFT array substrate 10 and the opposing substrate 20.

Note that, instead of forming the data line drive circuit 201 and the scanning line drive circuits 204 on the TFT array substrate 10, for example, a TAB (Tape Automated Bonding) substrate equipped with a driver LSI and a group of terminals provided to the periphery of the TFT array substrate 10 can electrically and mechanically be connected to each other via an anisotropic conductive film. Note that, although in the liquid crystal display device 100, a wave plate, a deflecting plate, and so on are disposed in appropriate orientations in accordance with a nature of the used liquid crystal, namely, the operational mode such as a TN (Twisted Nematic) mode or a STN (Super Twisted Nematic) mode, or other modes such as normally white mode or normally black mode, the illustration thereof will be omitted here. Further, if the liquid crystal display device 100 is configured to be used as a color display, color filters for red (R), green (G), and blue (B), for example, are formed with their protective films in the area of the opposing substrate 20 facing the respective pixel electrodes, described below, of the TFT array substrate 10.

In the image display area of the liquid crystal display device 100 having such a structure, as shown in FIG. 12, a number of pixels 100a are configured as a matrix, and each of the pixels 100a is provided with a TFT (a switching device) 30 for pixel-switching, and the data line 6a for supplying a pixel signal S1, S2, . . . ,or Sn is electrically connected to the source of the TFT 30. The pixel signals S1, S2, . . . , and Sn to be provided to the data lines 6a can respectively be supplied to each data line in this order, or can respectively be supplied to each group composed of a number of adjacent data lines 6a. Further, the scanning lines 3a are electrically connected to the gates of the TFTs 30, and it is configured that the scanning signals G1, G2, . . . , Gm are respectively supplied to the scanning lines 3a at a predetermined timing in forms of pulses in this order.

Note that, although the configuration, in which the TFTs 30 are used as the switching elements for driving the liquid crystal display device 100, is described in the above embodiment, it can be applied to, for example, an organic EL (electroluminescence) display device other than the liquid crystal display device 100. The organic EL display device having a structure, in which a thin film including an inorganic or an organic fluorescent compound is sandwiched by a cathode and an anode, is an element that generates excitons by injecting electrons and holes to the thin film and recombining them, and emits light by utilizing emission (fluorescence or phosphorescence) of light caused by deactivation of the excitons. And, a light-emitting full-color EL device can be manufactured by respectively patterning on the substrate provided with TFTs 30 described above using the light emitting layer forming materials as the wiring pattern functional fluid X, namely materials respectively presenting red, green, and blue selected from the fluorescent materials used for organic EL display elements, and a material for forming a hole injection/electron transport layer as the wiring pattern functional fluid X. The range of the device (electro-optic device) of the invention also includes such an organic EL device.

Note that, as the device (electro-optic device) according to the invention, in addition to the above devices, a PDP (Plasma Display Panel), and a surface-conduction electron-emitter display, which utilizes a phenomenon of generating electron emission by making current flow in parallel with the surface of a thin film having the small area provided on the substrate, can be adopted.

Electronic Instrument

Hereinafter, an electronic instrument equipped with the liquid crystal display device 100 according to the embodiment of the invention will be described.

FIG. 13 is a perspective view showing an example of a mobile phone. In FIG. 13A, a main body 600 of the mobile phone, and a liquid crystal display section 601 equipped with the liquid crystal display device 100 according to the above embodiment are illustrated.

The main body 600 of the mobile phone shown in FIG. 13 is equipped with the liquid crystal display device 100 according to the embodiment described above, and the liquid crystal display device is manufactured using the method of forming the pattern including the bank structure of the embodiment described above, thus obtaining high quality and high performance. Note that, although the electronic instruments according to the present embodiment are described as being equipped with the liquid crystal display device, they can be electronic instruments equipped with another electro-optic device such as an organic electroluminescence display device or a plasma display device.

Although the invention is explained citing some preferred embodiments as above, the invention is not limited to each of the above embodiments, but includes modification described below, and can be set to any other specific structures or shapes within a range capable of achieving the advantages of the invention.

### MODIFIED EXAMPLE 1

In the embodiment described above, firstly the wiring pattern functional fluid X is disposed to the first region Gh and dried, and then the wiring pattern functional fluid X is further disposed to the third region Ga and calcined, but the invention is not so limited. For example, the order of the processes can be reversed, namely the wiring pattern functional fluid X is firstly disposed to the third region Ga and dried, then the wiring pattern functional fluid X is further disposed to the first region Gh to be calcined. By thus executing the processes, similarly to the embodiment described above, the resulting film has the even film thickness in the gate electrode 11. Moreover, the number of insufficient film thicknesses or breaking patterns can be suppressed to a small amount. Since the gate electrode 11 and the gate wiring 12 can be formed to have substantially the same and even thicknesses, the same advantages as the embodiments can be obtained. Further, since the wiring pattern 79 of the multi-layered film can also be formed using the same method, the same advantages as the embodiments can be obtained.

### MODIFIED EXAMPLE 2

Although, in the embodiments described above, the periphery of the third region Ga has a circular arc, the invention is not so limited. For example, a square shape or a rectangular shape can be adopted. Even by thus arranged, since the wiring pattern functional fluid X disposed to the third region Ga flows into the second region Gd by the capillary phenomenon, the same advantages as the embodiments can be obtained.

### MODIFIED EXAMPLE 3

Although, in the embodiments described above, the height of the bottom 35 of the third region Ga is set to be the same as those of the first region Gh and the second region Gd, the invention is not so limited. For example, the bottom 35 of the third region Ga can be set higher than those of the first region Gh or the second region Gd. Even by thus arranged, since the wiring pattern functional fluid X disposed to the third region Ga flows into the second region Gd by the capillary phenomenon, the same advantages as the embodiments can be obtained.

### MODIFIED EXAMPLE 4

Although, in the embodiments described above, the height of the bottom 35 of the third region Ga is set to be the same as those of the first region Gh and the second region Gd, the invention is not so limited. For example, the bottom 35 of the third region Ga can be set lower than those of the first region Gh or the second region Gd. Even by thus arranged, although the lower height of the third region Ga causes the capacity of the third region Ga is increased, by increase an amount of wiring pattern functional fluid X disposed in unit time, the same advantages as the embodiments can be obtained.

What is claimed is:

1. A method of forming a wiring pattern in a predetermined area on a substrate using a droplet ejection process, comprising:
(a) forming a recess section for disposing a functional fluid in the predetermined area so that the predetermined area has a first region, a second region connected to the first region, and the third region connected to the second region, the second region having a narrower width than the first region and the third region;
(b) ejecting the functional fluid containing a material for the wiring pattern to the first region;
(c) drying the functional fluid ejected to the first region to form a first film;
(d) ejecting the functional fluid to the third region; and
(e) drying the functional fluid ejected to the third region to form a second film.

2. The method of forming a wiring pattern according to claim 1, wherein the step (a) includes
(a1) forming a bank surrounding the predetermined area on the substrate.

3. The method of forming a wiring pattern according to claim 1, wherein
a part of the wiring pattern formed on the predetermined area corresponding to the second region forms a gate electrode.

4. The method of forming a wiring pattern according to claim 1, wherein
the shape of the third region includes a circular arc in a part of an outer periphery.

5. The method of forming a wiring pattern according to claim 1, wherein
the wiring pattern includes a plurality of films different from each other disposed in the recess section, each of the films corresponding to a pair of the first and the second films, and
the steps (b), (c), (d), and (e) are executed for each of the films to stack the films.

6. A method of manufacturing a device including a wiring pattern formed in a predetermined area on a substrate using a droplet ejection process, comprising:
(f) forming the wiring pattern on the substrate using the method of forming the wiring pattern according to claim 1.

7. The method of manufacturing a device according to claim 6, wherein
the wiring pattern includes a gate electrode and a gate wiring.

8. A wiring pattern in a predetermined area formed on a substrate using a droplet ejection process, comprising:
a first region;
a second region connected to the first region;
a third region connected to the second region, the second region having a narrower width than the widths of the first region and the third region;
a first film formed in the first region and the second region by ejecting functional fluid to the first region and then drying the functional fluid; and
a second film formed in the second region and the third region by ejecting the functional fluid to the third region and then drying the functional fluid.

9. The wiring pattern according to claim 8, further comprising:
a recess section formed on the substrate and corresponding to the wiring pattern, wherein the recess section is defined by a bank surrounding the wiring pattern.

10. The wiring pattern according to claim 8, wherein
the second region of the wiring pattern forms a gate electrode.

11. The wiring pattern according to claim 8, wherein
the shape of the third region includes a circular arc in a part of an outer periphery.

12. The wiring pattern according to claim 9, wherein
the wiring pattern includes a plurality of films different from each other disposed in the recess section, and
the films each corresponding to a pair of the first film and the second film are stacked each other.

13. A device comprising:
a substrate; and
a wiring pattern according to claim 8.

14. The device according to claim 13, wherein
the wiring pattern includes a gate electrode and a gate wiring.

15. An electro-optic device comprising the device according to claim 13.

16. An electronic instrument comprising the electro-optic device according to claim 15.
